(19) United States
(12) Patent Application Publication
(10) Pub. No.: US 2006/0077730 A1
(43) Pub. Date: Apr. 13, 2006

(54) Memory control module and method for operating a memory control module

(76) Inventors: Andreas Jakobs, Munchen (DE); Christian Mueller, Woerth (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/241,042

(22) Filed: Sep. 30, 2005

(30) Foreign Application Priority Data
Sep. 30, 2004 (DE) 10 04 048 056.7-5

(51) Int. Cl. G11C 7/00

(52) U.S. Cl. 365/193

(57) ABSTRACT

The invention relates to a method for transmitting memory data from a memory to a memory control module, in which method a read command is transmitted from the memory control module to the memory, and the memory data which correspond to the read command are transmitted from the memory to the memory control module, a sampling control signal which controls the acceptance of the memory data into the memory control module being transmitted from the memory to the memory control module in parallel with the memory data. In order to avoid defective data transmission between the memory and the memory control module as reliably as possible, the sampling control signal is transmitted with a preamble which indicates the imminent beginning of data transmission, for the sampling control signal to be monitored for the presence of the preamble, and for a data input amplifier of the memory control module to be switched on only when the presence of the preamble is detected.

### CROSS-REFERENCE TO RELATED APPLICATIONS

This application claims foreign priority benefits under 35 U.S.C. §119 to co-pending German patent application number DE 10 2004 048 056.7-5, filed 30 Sep. 2004. This related patent application is herein incorporated by reference in its entirety.

### BACKGROUND OF THE INVENTION

1. Field of the Invention

The invention generally relates to a method for transmitting memory data from a memory to a memory control module which can be used, for example, to read stored memory data from a semiconductor memory, for example a DRAM memory and to transmit them to a memory control module (also usually referred to in the specialist terminology as a memory controller for short).

2. Description of the Related Art

FIG. 1 illustrates, by way of example, an arrangement which is known from personal computers and comprises a memory control module 10 and two memories 20 and 30 which are connected to the latter. For the purposes of communication between the memory control module 10 and the two memories 20 and 30 (which may be semiconductor memories, for example DRAMs), a clock signal CLK for transmitting the command and address data CA and a further clock signal DQS (which forms a “strobe signal” and will be referred to below as a sampling control signal) for transmitting memory data DQ are sent. In this case, the term “memory data” is to be understood as meaning the “useful data” which are stored in one of the two memories 20 or 30 or are read from the latter.

In order to write memory data, the memory control module 10 sends the corresponding write command and the associated memory address, via the associated CA line, to the respective memory 20 or 30 which receives this information, as far as possible, in synchronism with the clock signal CLK. In order to achieve this, the command and address data CA and the clock signal CLK have, as far as possible, identical propagation times from the memory control module 10 to the respective associated memory 20 or 30. After a certain waiting time (referred to below as the write latency WL), the memory control module 10 then sends the associated memory data DQ to the respective memory 20 or 30, to be precise together with the strobe or sampling control signal DQS which initiates or at least “concomitantly initiates” acceptance of the memory data DQ into the respective memory 20 or 30.

The write latency WL is calculated by counting pulses of the clock signal CLK in the memory 20 or 30; there should therefore preferably be a prescribed phase relationship between the data signal of the memory data DQ and the sampling control signal DQS and also the clock signal CLK. In the case of DRAM memories, the prescribed phase relationship is usually specified as the “tDQSS” parameter. Compliance with this prescribed phase relationship can be ensured, for example, by carefully dimensioning the DQ/DQS conductor tracks relative to the clock signal CLK line; alternatively, the DQ/DQS signals may also be selectively delayed relative to the clock signal CLK in the memory control module 10 in order to achieve the prescribed phase relationship. For the rest, different propagation times from the memory control module 10 to the respective memories 20 and 30 within the overall arrangement are of no consequence since the CLK clock signal and the DQ/DQS signals move in the same “direction”—that is to say respectively toward the selected memory 20 or 30—during the write operation.

In order to read memory data from one of the two memories 20 and 30, the memory control module 10 sends its read command, together with its clock signal CLK, to the selected memory via the corresponding command and address data CA. The respectively addressed memory 20 or 30 uses the clock signal CLK to count a certain read latency RL and then sends its memory data DQ, together with its own sampling control signal DQS, back to the memory control module 10. In the memories 20 and 30, a suitable delay locked loop (DLL) circuit ensures that the memory data DQ and the sampling control signal DQS are sent in phase with the clock signal CLK of the memory control module 10. The time at which the memory data will arrive at the memory control module 10 is calculated, with reference to the transmission of the read command CA by the memory control module 10, as follows:
tData=tfCA+RL*tCK+tfDQS
tfCA denotes the propagation time of the clock signal CLK from the memory control module 10 to the respective memory 20 or 30. tCK denotes the period of the clock signal CLK, and tfDQS denotes the propagation time of the memory data DQ from the memory 20 or 30 back to the memory control module 10.

If the situation (shown in FIG. 1) in which two or more memories 20 or 30 are arranged at a different electrical distance from the memory control module 10 and thus have different electrical signal propagation times is now considered, this means that the memory data DQ from the two memories 20 and 30 will arrive at the memory control module 10 at different times. In addition, both arrival times will generally be completely out of sync with the internal clock CLK of the memory control module 10.

The corresponding temporal profile of data signal transmission is illustrated, by way of example, in FIG. 2. It can be seen that the memory 30 (“inner DRAM”) which is arranged closer to the memory control module 10 sends its memory data DQ to the memory control module 10 sooner than the memory 20 (“outer DRAM”) which is arranged further away. This may result in errors when reading memory data.

### SUMMARY OF THE INVENTION

On the basis of the method (explained above), the invention is now based on the object of improving said method in such a manner that defective data transmission between the memory and the memory control module is avoided as reliably as possible.

Accordingly, the invention provides for a sampling control signal which has a preamble and indicates the imminent beginning of data transmission to be evaluated in addition to the memory data. An associated data input amplifier of the memory control module is switched on only when the presence of the preamble is detected in the memory control module.

A fundamental advantage of the method according to the invention resides in the fact that, in this method, the data input amplifier(s)—which is/are connected to the memories—of the memory control module is/are switched on solely when data are actually being transmitted. This prevents the data input amplifiers being active and the memory control module being in the receiving mode if data are not actually being transmitted and undefined states are being transmitted via the respective data lines. Specifically, the method according to the invention thus optimizes the point in time at which the data input amplifiers of the memory control module are activated by ensuring that the data input amplifiers are activated only for a relatively short time right around the actual transmission of the memory or useful data. This prevents states which are not erroneously undefined on the DQ/DQS bus being “misinterpreted” as useful or memory data. In order to deliberately control the data input amplifiers in a corresponding manner, the sampling control signal which is sent to the memory control module together with the memory data is monitored for the presence of a preamble which indicates the imminent beginning of data transmission; the associated data input amplifier of the memory control module is switched on only when such a preamble is present.

In summary, the method according to the invention thus ensures that the data input amplifier(s) of the memory control module cannot be switched on prematurely and cannot receive “incorrect” data.

One advantageous refinement of the method provides for each memory connection of the memory control module to be respectively individually monitored for the presence of a preamble of the associated sampling control signal, and for each of the data input amplifiers (input amplifiers) of the memory control module to be respectively switched on solely when such a preamble is detected. This refinement of the method thus ensures that each of the input amplifiers of the memory control module is respectively always switched on at the “right” or optimum point in time.

The sampling or strobe signal is preferably a differential signal having inverse individual signals, or individual signals which have been phase-shifted through 180°, which have a so-called tristate—that is to say a high-impedance state—in the inactive state.

In the case of a differential sampling control signal, the presence of a preamble is preferably deduced if the two individual signals each have a signal state that differs from their tristate.

In a particularly preferred manner, the input amplifiers are respectively switched on only when the respective preamble has been detected and when, in addition, a separate data signaling signal which announces data transmission announces imminent data transmission. The separate data signaling signal used may be, for example, the so-called “ddr_rd_en2” signal which is generated in DRAM memories based on the DDR1 or the DDR2 standard.

In order to ensure that the input amplifiers of the memory control module are not active for longer than is absolutely necessary in order to receive the memory data, the input amplifiers are switched off after a prescribed number of signal changes of the sampling control signal. The prescribed number of sampling control signal changes may correspond to the burst length of data transmission, for example. Alternatively, the prescribed number of sampling control signal changes may correspond to an integer multiple of this burst length.

Alternatively, the input amplifiers of the memory control module may also be switched off after a postamble of the sampling control signal has been received.

The read command for reading memory data from the memory may be, for example, control data which comprise command data for giving rise to the read operation and address data for defining the memory address (which is to be read) of the memory.

In the case of a differential sampling control signal, the presence of a preamble can be detected in a particularly simple and thus advantageous manner by comparing the two differential individual signals of the sampling control signal with a respective associated reference voltage. The presence of a preamble is deduced if one of the two individual signals is greater than the associated reference voltage and the respective other individual signal is less than the associated reference voltage. The two reference voltages preferably respectively differ from the mid-voltage between the maximum voltage level and the minimum voltage level of the two differential individual signals. By way of example, one of the two reference voltages may be greater than the mid-voltage and the other reference voltage may be less than the mid-voltage.

The two comparison results of the comparison between the individual signal and the reference voltage can be evaluated in a particularly simple and thus advantageous manner using an AND gate, for example.

In addition, the invention relates to a memory control module having at least one connection to a memory, the at least one connection having at least one sampling control signal input for receiving a sampling control signal of the memory and one data input for receiving the memory data of the memory.

As regards the advantages of the memory control module according to the invention, reference is made to the statements made above in connection with the method according to the invention.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a conventional arrangement showing a memory control module connected to two memories.

FIG. 2 illustrates a temporal profile of data signal transmission of the arrangement shown in FIG. 1.

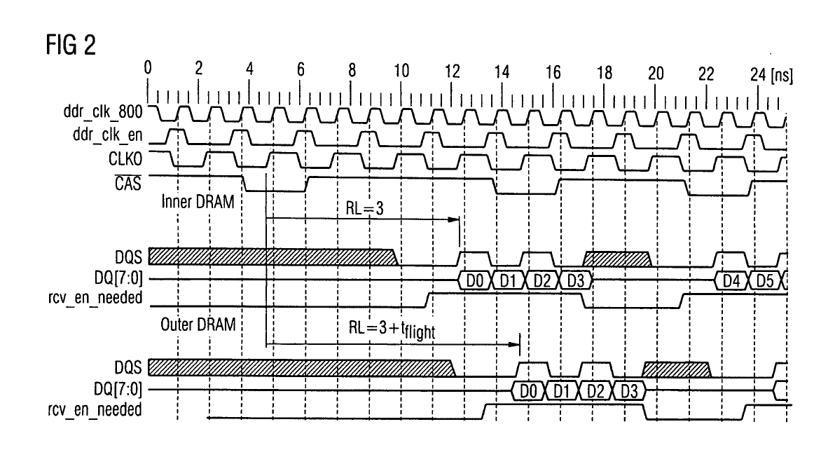

FIG. 3 shows an exemplary embodiment of an arrangement which is used, by way of example, to explain the method according to the invention and, in addition, has a memory control module according to the invention,

FIG. 4 shows the temporal profile of an operation of reading from a memory of the arrangement shown in FIG. 3, and

FIG. 5 shows an exemplary embodiment of a preamble detection device for the memory control module shown in FIG. 3.

### DETAILED DESCRIPTION OF THE PREFERRED EMBODIMENT

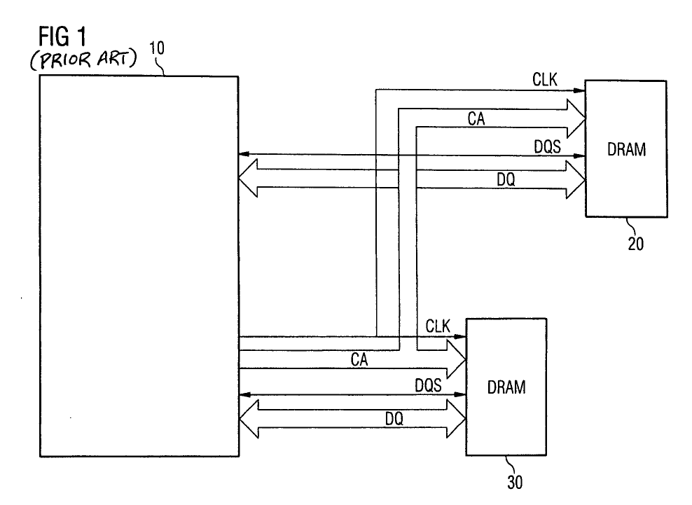

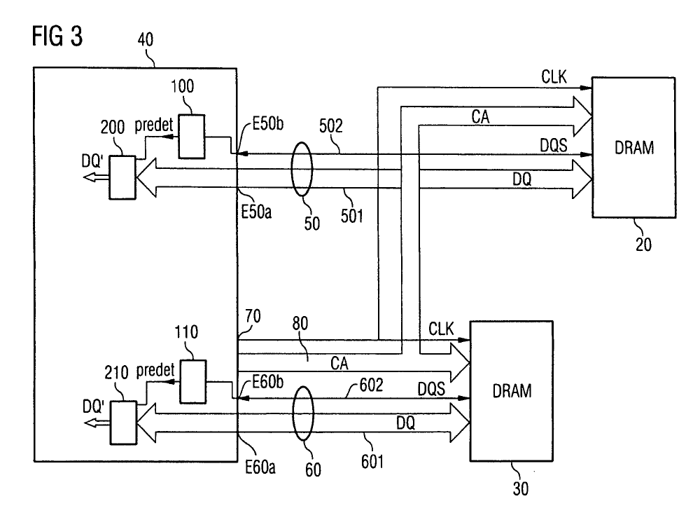

FIG. 3 illustrates an arrangement comprising a memory control module 40 and two DRAM memories 20 and 30. The two DRAM memories 20 and 30 correspond to the two memories shown in FIG. 1. The memory control module 40 shown in FIG. 3 differs from the memory control module 10 shown in FIG. 1 by virtue of the configuration of the signal input, as will be explained in more detail below.

The memory control module 40 has a first connection 50 for the memory 20. This first connection 50 is provided with a data signal connection E50a and a sampling control signal connection E50b. Connected to the data signal connection E50a is a first signal line or a data bus 501 for transmitting the memory data DQ which are stored in the memory 20 by the memory control module or are read back to the memory control module 40 from the memory 20; a signal line 502 for transmitting the strobe or sampling control signal DQS is connected to the sampling control signal connection E50b. The two signal lines 501 and 502 are each of bidirectional design, with the result that memory data can be both written to, and read from, the memory 20.

In order to connect the second memory 30, the memory control module 40 has a second connection 60 having a data signal connection E60a and a sampling control signal connection E60b. A first signal line or a data bus 601 for transmitting the memory data DQ is connected to the data signal connection E60a; a signal line 602 for transmitting the strobe or sampling control signal DQS is connected to the sampling control signal connection E60b. The two signal lines 601 and 602 may each be operated bidirectionally in order to make it possible to store memory data in, and read memory data from, the memory 30.

In addition, the memory control module 40 has a clock output 70 which is used to transmit a clock signal CLK to the two memories 20 and 30. There is also a command bus 80 which can be used to transmit command and address data CA to the two memories 20 and 30.

It can be seen in FIG. 3 that a respective preamble detection device 100 and 110 is connected to the two connections 50 and 60 in the memory control module 40. The two preamble detection devices 100 and 110 are each used to monitor the two signal lines 502 and 602 and to evaluate the sampling control signal DQS (which is transmitted on said signal lines) for the presence of a preamble.

A respective data input amplifier 200 and 210—referred to below as input amplifier for short—is connected to the two preamble detection devices 100 and 110 on the output side. One of the two input amplifiers 200 is also connected, on the input side, to the signal line 501 and amplifies the memory data signals DQ arriving at the connection 50 of the memory control module so as to form amplified memory data signals DQ′; the other input amplifier 210 is also connected, on the input side, to the signal line 601 and amplifies the memory data signals DQ arriving at the connection 60 of the memory control module so as to form amplified memory data signals DQ′.

The other components of the memory control module 40, to which the input amplifiers 200 and 210, inter alia, are connected, are not illustrated in FIG. 3 for the sake of clarity; these components may correspond, for example, to the customary components in conventional memory control modules.

In the arrangement shown in FIG. 3, the memory control module 40 can be used, for example, to read the memory 20; this is now explained in detail below. The following statements correspondingly apply to reading the further memory 30.

In order to read the memory 20, the memory control module 40 first of all sends appropriate command and address data CA to the memory 20 via the command bus 80. In this case, the command and address data comprise the command for reading the memory and, in addition, the address data of the memory cell or memory cells to be read.

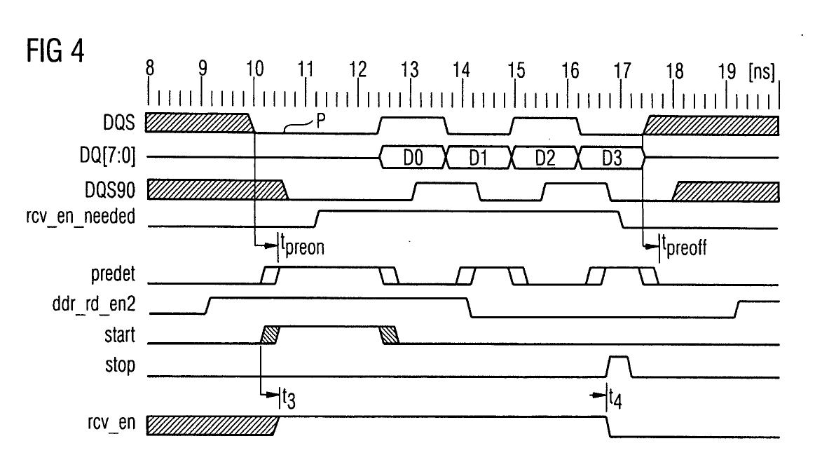

As soon as the memory 20 receives the read command of the memory control module 40, it counts a certain read latency RL and then sends the requested memory data DQ to the memory control module 40 via the signal line 501. Before sending the memory data DQ, the memory 20 will additionally send a sampling control signal DQS to the memory control module 40 via the signal line 502. This sampling control signal DQS is used to inform the memory control module 40 of the clock which is used to transmit the memory data DQ via the signal line 501 and in accordance with which the memory data DQ have to be evaluated by the memory control module 40. In this case, the memory 20 provides the sampling control signal DQS with a preamble whose profile is illustrated in FIG. 4.

It can be seen in FIG. 4 that, at a time t=10 ns, the sampling control signal DQS changes from an undefined state to a defined state. At this time t=10 ns, the sampling control signal DQS assumes a logic “0”. This state is interpreted by the preamble detection device 100 as a preamble (P); as soon as such a preamble (P) is detected by the preamble detection device 100, the latter sends a switch-on signal predet, with a certain time delay tₚᵣₑₒₙ, to the input amplifier 200 which is then switched on. FIG. 4 uses the signal rcv_en to show activation of the input amplifier 200. It can be seen that the signal rcv_en assumes a logic 1 when the switch-on signal predet is present, thus signaling that the input amplifier 200 is active and can receive data signals DQ of the memory 20.

The input amplifier 200 is preferably switched on only when both the switch-on signal predet of the preamble detection device 100 and additionally an announcement signal ddr_rd_en2 which signals or announces the arrival of the memory data DQ are present. The announcement signal ddr_rd_en2 is generated by the memory control module 40 after it has transmitted its read command to the memory 20, to be precise immediately afterward or after a prescribed latency.

As soon as the signal rcv_en has a logic “1”, further signal changes of the predet signal are ignored; the input amplifier 200 is switched off and thus the signal rcv_en is reset to a logic “0” after a prescribed number of DQS changes—the so-called burst length (BL) which is the same for all read operations—or after an integer multiple of this length.

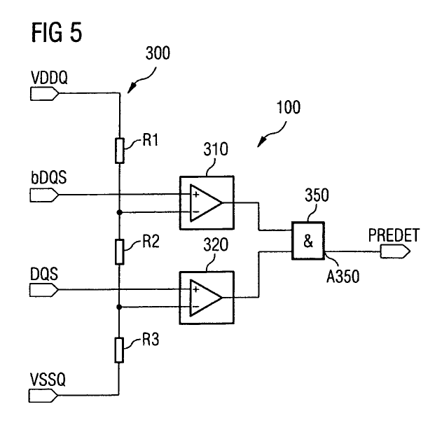

FIG. 5 shows an exemplary embodiment of the two preamble detection devices 100 and 110. It is possible to see a voltage divider device 300 which is formed by three electrical resistors R1, R2 and R3 which are preferably of the same size. The “negative” connection (inverting connection) of a first comparator 310 is connected to the junction point between the two resistors R1 and R2. The “positive connection” (noninverting connection) of a second comparator 320 is connected to the junction point between the two resistors R2 and R3.

The sampling control signal DQS is a differential signal comprising the two individual signals DQS and bDQS which are complementary to one another; one individual signal DQS is connected to the “negative connection” of the second comparator 320 and the other individual signal bDQS is connected to the “positive connection” of the first comparator 310.

On the output side, the two comparators are connected to a logic “AND” gate 350 which generates, at its output A350, the switch-on signal predet of the preamble detection device 100 or 110.

The preamble detection device 100 or 110 functions as follows:

If the differential sampling control signal DQS is inactive and accordingly has its high-impedance tristate, the two comparators 310 and 320 generate a logic “0” at their output, with the result that the predet signal will also have a logic “0”. The associated input amplifier 200 or 210 thus remains switched off.

As soon as the differential sampling control signal DQS indicates an active state and bDQS assumes its “high” level (logic “1”) and DQS assumes its “low” level (logic “0”), the two comparators 310 and 320 generate a logic “1” at their output, with the result that the predet signal will also have a logic “1”. The associated input amplifier 200 or 210 is thus switched on.

As can be discerned from the above statements, the predet signal also signals a logic “0” when one individual signal bDQS assumes a logic “0” and the other individual signal assumes a logic “1”. However, this does not play a fundamental role since, in spite of everything, the change from the tristate to the “preamble” state is reliably detected and the associated input amplifier is reliably switched on.

While the foregoing is directed to embodiments of the present invention, other and further embodiments of the invention may be devised without departing from the basic scope thereof, and the scope thereof is determined by the claims that follow.

What is claimed is:

1. A method for transmitting memory data from a memory to a memory control module, comprising:
transmitting a read command from the memory control module to the memory;
transmitting the memory data which correspond to the read command from the memory to the memory control module;
transmitting a data strobe signal from the memory to the memory control module in parallel with the memory data, wherein the data strobe signal controls the acceptance of the memory data into the memory control module;
monitoring for a presence of a preamble of the data strobe signal indicating the imminent beginning of data transmission; and
switching a data input amplifier of the memory control module on only if, at a minimum, the presence of the preamble is detected.

2. The method of claim 0, wherein the data strobe signal sent is a differential sampling control signal having individual signals which are complementary to one another and each having a high-impedance state in an inactive state.

3. The method of claim 2, wherein the presence of the preamble is deduced if the two individual signals each have a signal state that differs from the high-impedance state.

4. The method of claim 2, wherein the presence of the preamble is detected by:
comparing the two differential individual signals of the data strobe signal with reference voltages; and
determining the presence of the preamble if (i) one of the two individual signals is greater than the reference voltage associated with the one of the two individual signals and (ii) the other one of the two individual signals is less than the reference voltage associated with the other of the two individual signals.

5. The method of claim 4, wherein the two reference voltages respectively differ from the mid-voltage between the maximum possible voltage and the minimum possible voltage of the differential individual signals.

6. The method of claim 5, wherein one reference voltage is greater than the mid-voltage and one reference voltage is less than the mid-voltage.

7. The method of claim 0, wherein, in addition to detecting the preamble, the data input amplifier is only switched on if a separate data signaling signal is detected, the separate data signaling signal indicating the imminent data transmission.

8. The method of claim 0, wherein the data input amplifier which has been switched on, is switched off after a prescribed number of signal changes of the data strobe signal.

9. The method of claim 8, wherein the prescribed number of signal changes corresponds to the burst length of data transmission.

10. The method of claim 0, further comprising switching the data input amplifier off upon receiving a postamble of the data strobe signal.

11. The method of claim 0, wherein the read command contains command data, which signal a read operation, and address data which define one or more memory cells of the memory devices to be read.

12. A method for transmitting memory data from memory devices to a memory control module, comprising:
transmitting a respective read command from a memory control module to two or more memory devices, the memory control module and the two or more memory devices being connected by respective buses;
transmitting memory data which correspond to the respective read command from the respective memory devices to the memory control module;
transmitting a respective data strobe signal from the respective memory devices to the memory control module in parallel with the respective memory data, wherein the respective data strobe signals control the acceptance of the respective memory data into the memory control module;
monitoring each bus for a presence of a respective preamble of the respective data strobe signal indicating the imminent beginning of data transmission from the respective memory device; and
switching a respective data input amplifier of the memory control module on only if, at a minimum, the presence of the respective preamble is detected.

13. The method of claim 12, wherein the data strobe signals sent are differential sampling control signals each having individual signals which are complementary to one another and each having a high-impedance state in an inactive state.

14. The method of claim 13, wherein the presence of the respective preambles is deduced if the two respective individual signals of a given preamble each have a signal state that differs from the high-impedance state.

15. The method of claim 13, wherein the presence of each respective preamble is detected by:
comparing two differential individual signals of the respective data strobe signal with reference voltages; and
determining the presence of the preamble if (i) one of the two individual signals is greater than the reference voltage associated with the one of the two individual signals and (ii) the other one of the two individual signals is less than the reference voltage associated with the other of the two individual signals.

16. The method of claim 15, wherein the two reference voltages respectively differ from the mid-voltage between the maximum possible voltage and the minimum possible voltage of the differential individual signals.

17. The method of claim 16, wherein one reference voltage is greater than the mid-voltage and one reference voltage is less than the mid-voltage.

18. The method of claim 12, wherein, in addition to detecting the respective preambles, the respective data input amplifiers are only switched on if a separate data signaling signal is detected, the separate data signaling signal indicating the imminent data transmission.

19. The method of claim 12, wherein each data input amplifier which has been switched on is respectively switched off after a prescribed number of signal changes of the respective data strobe signal.

20. The method of claim 19, wherein the prescribed number of signal changes corresponds to the burst length of data transmission.

21. The method of claim 12, further comprising switching the data input amplifier off upon receiving a postamble of the data strobe signal.

22. A memory control module, comprising:
at least one connection for communicating with a memory device, the at least one connection comprising at least one data strobe signal connection for receiving a data strobe signal of the memory device and one data signal connection for receiving the memory data of the memory device;
a data input amplifier connected to the data signal connection; and
a preamble detection device connected to the data strobe connection, the preamble detection device configured to monitor the sampling control signal connection for the presence of a preamble of the data strobe signal and, when a preamble is present, issue an enable signal to the data input amplifier, thereby enabling the data input amplifier.

23. The memory control module of claim 21, wherein the preamble detection device comprises at least one logic gate.

24. The memory control module of claim 21, wherein the preamble detection device comprises at least one comparator.

25. The memory control module of claim 21, wherein the data strobe signal comprises a differential sampling control signal which has individual signals that are complementary to one another; and wherein the preamble detection device comprises:
two comparators, to which respective ones of the individual signals are applied; and
an AND gate which logically combines the two output signals from the two comparators and generates the enable signal.
